(19) United States
(12) Patent Application Publication
(10) Pub. No.: US 2024/0147742 A1
(43) Pub. Date: May 2, 2024

(54) METHOD FOR MANUFACTURING HIGH-PERFORMANCE INDOOR PHOTOVOLTAIC CELL USING SELF-ASSEMBLED MONOLAYERS AND INDOOR PHOTOVOLTAIC CELL MANUFACTURED THEREBY

(71) Applicant: KOREA UNIVERSITY RESEARCH AND BUSINESS FOUNDATION, Seoul (KR)

(72) Inventors: Jae Won SHIM, Seoul (KR); Tae Hyuk KIM, Seoul (KR)

(73) Assignee: KOREA UNIVERSITY RESEARCH AND BUSINESS FOUNDATION, Seoul (KR)

(21) Appl. No.: 18/375,684

(22) Filed: Oct. 2, 2023

(30) Foreign Application Priority Data
Oct. 31, 2022 (KR) 10-2022-0141987

(51) Int. Cl. H10K 30/20

(52) U.S. Cl. CPC H10K 30/20; H10K 85/6572

(57) ABSTRACT

Disclosed are a method for manufacturing a high-performance indoor photovoltaic cell using self-assembled monolayers and an indoor photovoltaic cell manufactured thereby. According to the present invention, provided is an indoor photovoltaic cell including: a transparent lower electrode passing through indoor light; a self-assembled single-layer based ultra thin 2PACz layer formed on the lower electrode with a predetermined thickness; an organic semiconductor layer formed on the 2PACz layer by mixing materials for forming a donor layer and an acceptor layer, and 2PACz, generating an exciton by the indoor light, and separating the exciton into a positive charge and a negative charge; and an upper electrode absorbing the negative charge.

### CROSS-REFERENCE TO RELATED APPLICATION

This application claims under 35 U.S.C. § 119(a) the benefit of Korean Patent Application No. 10-2022-0141987 filed on Oct. 31, 2022, the entire contents of which are incorporated herein by reference.

### BACKGROUND

### (a) Technical Field

The present invention relates to a method for manufacturing a high-performance indoor photovoltaic cell using self-assembled monolayers and an indoor photovoltaic cell manufactured thereby.

### (b) Background Art

Low efficiency of an indoor photovoltaic cell cannot guarantee the actual use as a power source, which requires significant improvement in power conversion efficiency and life of the indoor photovoltaic cell.

In particular, the number of carriers limited under the indoor lighting causes significant recombination loss between an organic semiconductor layer and an electrode.

The short circuit current density of the efficiency of the indoor photovoltaic cell affects the permeability of a lower electrode and a charge transport layer, and an open voltage is closely related to an energy band alignment between a work function of the lower electrode and the charge transport layer, and a filling rate is closely related to a recombination element generated in a charge transport channel.

Therefore, it is important to reduce the work function matching of the lower electrode and the recombination elements of the charge transport channel of the indoor photovoltaic cell.

### SUMMARY OF THE DISCLOSURE

In order to solve the problem in the prior art, the present invention is to provide a method for manufacturing a high-performance indoor photovoltaic cell using self-assembled monolayers and an indoor photovoltaic cell manufactured thereby, which can significantly reduce recombination through a high work function, effective energy level alignment, and transport loss reduction in a charge transport channel.

In order to achieve the object, according to an embodiment of the present invention, provided is an indoor photovoltaic cell including: a transparent lower electrode passing through indoor light; a self-assembled single-layer based ultra thin 2PACz layer formed on the lower electrode with a predetermined thickness; an organic semiconductor layer formed on the 2PACz layer by mixing materials for forming a donor layer and an acceptor layer, and 2PACz, generating an exciton by the indoor light, and separating the exciton into a positive charge and a negative charge; and an upper electrode absorbing the negative charge.

The 2PACz layer may be formed with a thickness of 3 nm or less.

The material for forming the donor layer may include at least one of PM6 and PM7, and the material for forming the acceptor layer may include at least one of Y6 and PC71BM.

In the indoor photovoltaic cell, vertical phase separation is made between the lower electrode and the organic semiconductor layer in the organic semiconductor layer by the 2PACz layer.

Trap assistance recombination and charge transport loss may be reduced by the vertical phase separation.

According to another embodiment of the present invention, provided is a method for manufacturing an indoor photovoltaic cell, including: forming a transparent lower electrode through which indoor light passes on a substrate; forming a self-assembled single-layer based ultra thin 2PACz layer with a predetermined thickness at an upper portion of the lower electrode; forming, on the 2PACz layer, an organic semiconductor layer generating an exciton by the indoor light by mixing materials for forming a donor layer and an acceptor layer, and 2PACz, separating the exciton into a positive charge and a negative charge, and forming an upper electrode absorbing the negative charge on the organic semiconductor layer.

According to the present invention, an indoor photovoltaic cell is manufactured by controlling an electrode surface work function and applying 2PACz to the inside of an organic semiconductor layer, thereby efficiently controlling a work function and minimizing charge recombination and energy loss.

### BRIEF DESCRIPTION OF THE DRAWINGS

FIG. 1 is a diagram illustrating a chemical structure of PM6(PBDB-T-2F), Y6(BTP-4F) and 2PACz([2-(9H-Carbazol-9-yl)ethyl]phosphonic Acid) used in an organic semiconductor layer (photovoltaic active layer) according to an embodiment of the present invention.

FIG. 2 is a diagram illustrating the absorbance of various films adopting the organic semiconductor layer and 2PACz.

FIG. 3 is a diagram illustrating an optical band gap of PM6, 2PACz/PM6 (dual layer), and PM6:2PACz (single layer, blend).

FIG. 4 is a diagram illustrating a work function for ITO/various films through ultraviolet photoelectric spectroscopy.

FIG. 5 is a diagram illustrating a dipole moment change mechanism.

FIG. 6 is a diagram illustrating depth profiles of 2PACz/PM6:Y6 and PM6:Y6:2PACz films obtained by using a flight time secondary ion mass spectroscopy.

FIG. 7 is a diagram illustrating surface morphological characteristics identified by grazing wide-angle X-ray scattering and expression roughness observed by a 3D scanning probe microscopy for each of 2PACz/PM6:Y6, PM6:Y6:2PACz, and 2PACz/PM6:Y6:2PACz.

FIG. 8 is an energy level schematic view of an indoor photovoltaic cell according to the exemplary embodiment.

FIG. 9 is a diagram illustrating a performance result of each organic indoor photovoltaic cell measured under an outdoor light (AM 1.5 G, light intensity: 100 mW/cm²) illumination.

FIG. 10 is a diagram illustrating external quantum efficiency (EQE).

FIG. 11 is a diagram illustrating a performance result of the indoor photovoltaic cell under an indoor light (LED 1000 lx, light intensity: 0.23 mW/cm², FL 1000 lx, light intensity: 0.27 mW/cm², HL 1000 lx, light intensity: 7.0 mW/cm²) illumination.

FIG. 12 is a diagram illustrating EQE_{EL} for identifying energy loss.

FIG. 13 is a diagram illustrating characteristics for each device under an indoor light source for identifying dependency on a J-V incident light intensity.

FIG. 14 is a diagram illustrating a representative Jₚₕ-V_{eff} characteristic curve under LED, FL, and HL 1000 lx illumination.

FIG. 15 is a diagram illustrating performance parameters (Normalized PCE, V_{OC}, J_{SC}, FF) for surrounding stability of each device.

### DETAILED DESCRIPTION

The present invention may be embodied in various modifications and various embodiments, and specific embodiments will be illustrated in the drawings and described in detail in the detailed description. However, it should be understood that this is not to limit the present invention to specific embodiments, and that the present invention covers all the modifications, equivalents and replacements included within the idea and technical scope of the present invention.

The terms used in the present specification are used only to describe specific embodiments, and are not intended to limit the present invention. A singular form includes a plural form unless the context clearly dictates otherwise. In this specification, it should be understood that term “include” or “have” indicates that a feature, a number, a step, an operation, a component, a part or the combination thereof described in the specification is present, but does not exclude a possibility of presence or addition of one or more other features, numbers, steps, operations, components, parts or combinations thereof, in advance.

In addition, the components of the embodiment described with reference to each drawing are not limitedly applied only to the corresponding embodiment, and may be implemented to be included in another embodiment within the scope of maintaining the technical idea of the present invention, and further, even if a separate explanation is omitted, it is natural that a plurality of embodiments may be re-implemented as one embodiment.

In addition, in the description with reference to the accompanying drawings, the same components are assigned the same or related reference numerals regardless of the reference numerals, and redundant descriptions thereof will be omitted. In describing the present invention, a detailed description of related known technologies will be omitted if it is determined that they unnecessarily make the gist of the present invention unclear.

An indoor photovoltaic cell consists of a transparent electrode (lower electrode), a hole transport layer, a photovoltaic active layer and an upper electrode, and an operation principle is as follows:
(1) light absorption, (2) exciton generation, (3) exciton movement, (4) exciton positive charge and negative charge separation, and (5) negative charge absorption of upper electrode.

In the operation principle of the indoor photovoltaic cell, the positive charge and the negative charge generated by light move to both electrodes according to a work function of a charge transport layer.

A generally and widely used hole transport layer (PEDOT:PSS) is limited to improving the performance of the photovoltaic cell by reducing light transmittance to the photovoltaic active layer due to vulnerability of oxygen and moisture in the atmosphere, and a high thickness (˜40 nm).

The present invention proposes a new method which can significantly reduce recombination through a high work function, effective energy level alignment, and transport loss reduction in a charge transport channel by simultaneously applying a single layer based ultra-thin 2PACz which is a self-assembled monolayer to the photovoltaic active layer and the lower electrode.

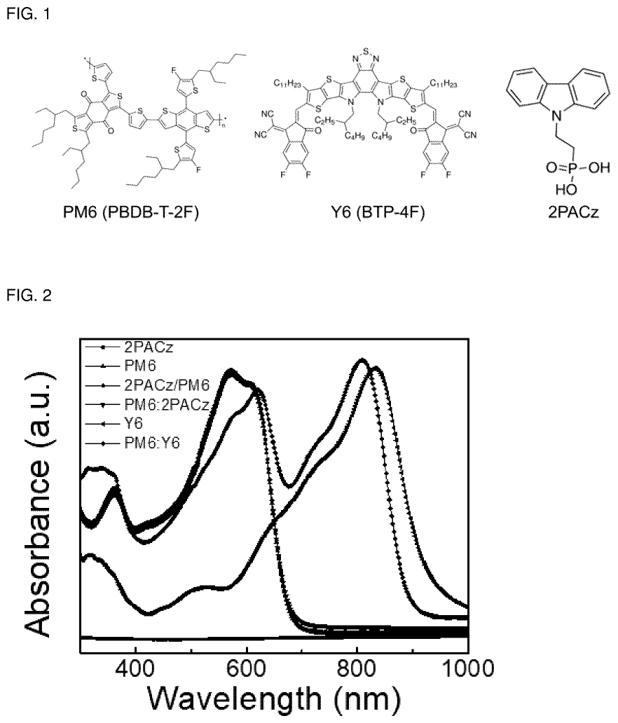

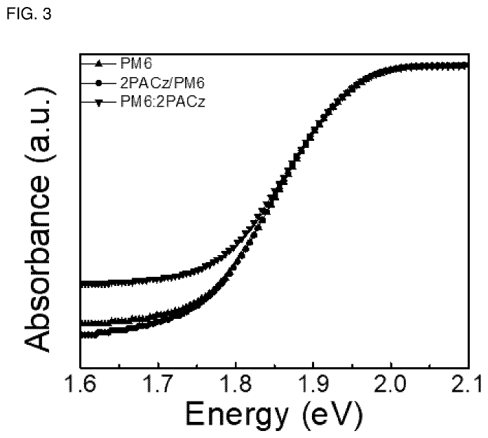

FIG. 1 is a diagram illustrating a chemical structure of PM6(PBDB-T-2F), Y6(BTP-4F) and 2PACz([2-(9H-Carbazol-9-yl)ethyl]phosphonic Acid) used in an organic semiconductor layer (photovoltaic active layer) according to an embodiment of the present invention, FIG. 2 is a diagram illustrating the absorbance of various films adopting the organic semiconductor layer and 2PACz, and FIG. 3 is a diagram illustrating an optical band gap of PM6, 2PACz/PM6 (dual layer), and PM6:2PACz (single layer, blend).

FIG. 1 exemplarily illustrates a case where PM6 is used as a material which may constitute a donor layer and Y6 is used as a material which may constitute an acceptor layer, which are used in the embodiment, and the donor layer and the acceptor layer may also use other materials.

FIG. 2 illustrates the absorbance of various films (2PACz, PM6:2PACz, 2PACz/PM6) manufactured based on the donor layer and 2PACz.

Here, PM6:2PACz is generated by mixing two materials, and 2PACz/PM6 is acquired by forming two materials on different layers.

Referring to FIG. 2, absorbances of pure PM6, and PM6:2PACz and 2PACz/PM6 are almost similar, and this indicates that PM6 added with 2PACz does not affect loss of a light absorption degree.

FIG. 3 illustrates an optical band gap of the pure PM6, and PM6:2PACz and 2PACz/PM6, and this proves that PM6 has small loss of a light absorption degree due to high transmittance of 2PACz.

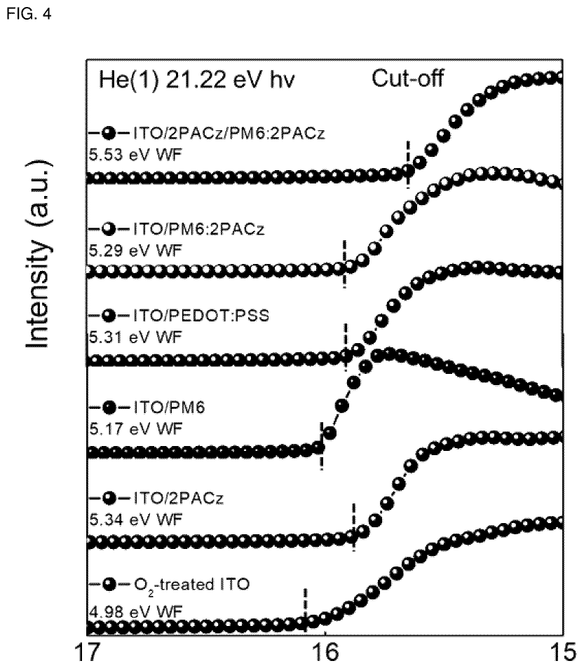

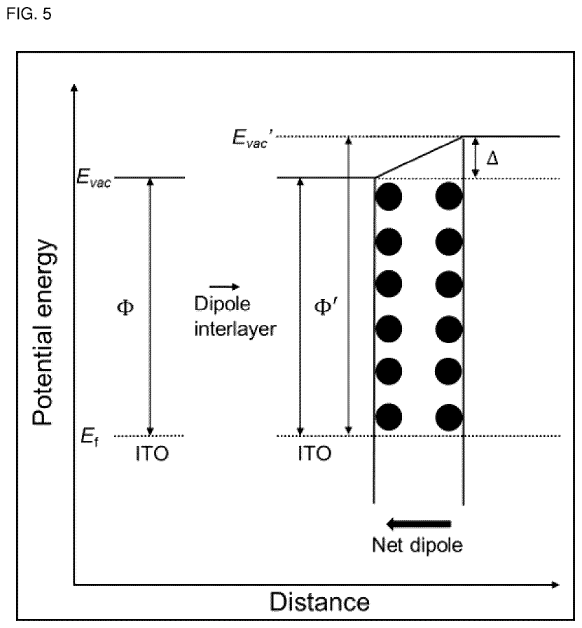

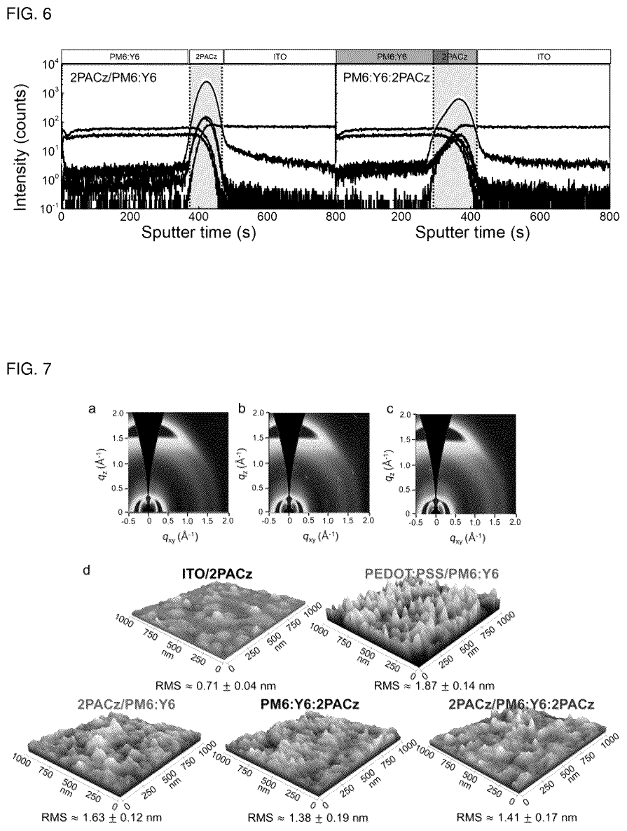

FIG. 4 is a diagram illustrating a work function for ITO/various films through ultraviolet photoelectric spectroscopy, FIG. 5 is a diagram illustrating a dipole moment change mechanism, and FIG. 6 is a diagram illustrating depth profiles of 2PACz/PM6:Y6 and PM6:Y6:2PACz films obtained by using a flight time secondary ion mass spectroscopy.

Referring to FIG. 4, when referring to a work function result for ITO/various films, ITO/2PACz (work function: 5.34 eV) shows a slightly higher work function than 5.31 eV which is the work function of ITO/PEDOT:PSS, and it may be predicted that this shows improved hole transport and extraction characteristics.

Further, the work function of the ITO/PM6:2PACz film which is 5.29 eV is a median value of ITO/PM6 and ITO/2PACz, which may indicate that the work function of ITO may be effectively controlled due to vertical phase separation of PM6:2PACz.

Here, optimized ITO/2PACz/PM6:2PACz shows a highest work function: 5.53 eV, and improves hole injection and electron blocking capabilities through an effective vacuum level change.

Referring to FIG. 5, 2PACz induces an effective dipole moment to ITO to control a surface work function of the ITO electrode.

FIG. 6 illustrates a spontaneous vertical phase separation effect of ITO/2PACz/PM6:Y6 dual layer and ITO/PM6:Y6:2PACz single layer.

Referring to FIG. 6, it can be identified that a gradient of 2PACz has a steep form on ITO/2PACz/PM6:Y6 dual layer thin films, while the gradient of 2PACz has a soft and wide sputter radius on ITO/PM6:Y6:2PACz single layer thin films.

This is evidence that in PM6:Y6:2PACz mixed layers, an effective vertical phase separation between ITO and PM6:Y6 has been observed, and indicates that 2PACz has induced efficient energy band bending.

FIG. 7 is a diagram illustrating surface morphological characteristics identified by grazing wide-angle X-ray scattering and expression roughness observed by a 3D atomic force microscopy for each of 2PACz/PM6:Y6, PM6:Y6:2PACz, and 2PACz/PM6:Y6:2PACz.

FIGS. 7A to 7C illustrate surface morphological characteristics with respect to an organic semiconductor layer (PM6:Y6:2PACz, 2PACz/PM6:Y6:2PACz) including 2PACz and other cases (2PACz/PM6:Y6).

Referring to FIGS. 7A to 7C, it can be seen that inter-modular crystallinity is not harmed due to efficient vertical phase separation in spite of the organic semiconductor layer including 2PACz.

FIG. 7D illustrates a result of examining surface roughness for various films through the atomic force microscopy.

Referring to FIG. 7D, it can be identified that the surface roughness for each film shows low RMC: 0.71 nm in ITO/2PACz, and shows RMS: 1.38 nm, 1.41 nm in the organic semiconductor layers (PM6:Y6:2PACz, 2PACz/PM6:Y6:2PACz) including 2PACz, respectively, which is lower than RMS: 1.63 nm of the 2PACz/PM6:Y6 layer in which 2PACz is not included in the organic semiconductor layer. The low value may be advantageous for minimizing the number of recombination portions due to generation of charge carriers of a limited number under an indoor illumination condition.

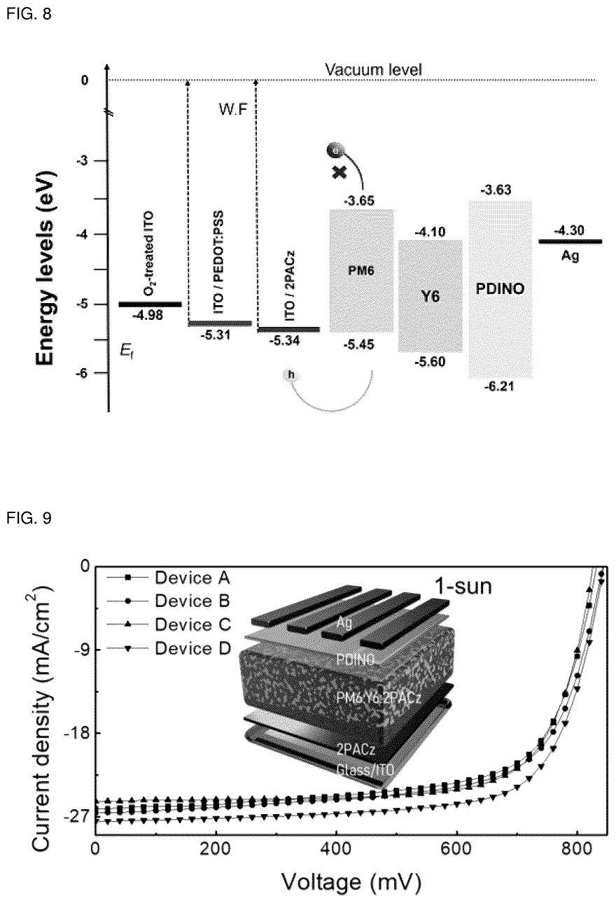

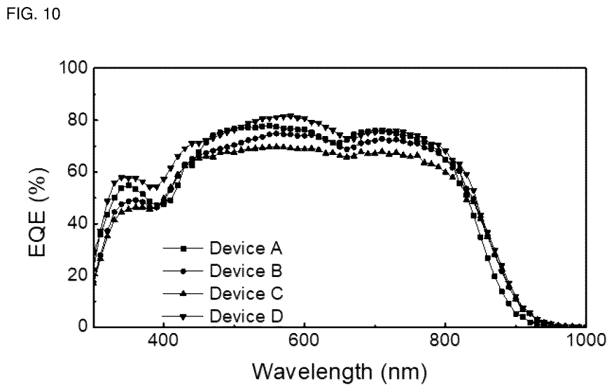

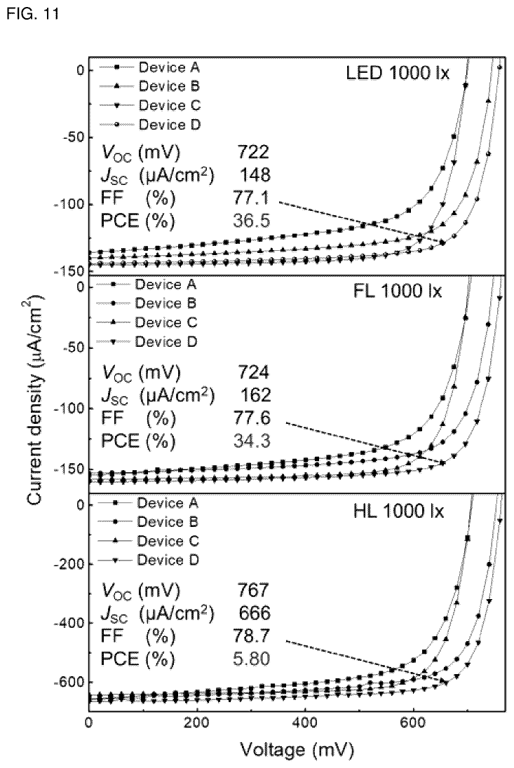

FIG. 8 is an energy level schematic view of an indoor photovoltaic cell according to the embodiment, FIG. 9 is a diagram illustrating the result of each organic indoor photovoltaic cell performance measured under an outdoor light (AM 1.5 G, light intensity: 100 mW/cm²) illumination, FIG. 10 is a diagram illustrating external quantum efficiency (EQE), and FIG. 11 is a diagram illustrating the result of the indoor photovoltaic cell performance under an indoor light (LED 1000 lx, light intensity: 0.23 mW/cm², FL 1000 lx, light intensity: 0.27 mW/cm², HL 1000 lx, light intensity: 7.0 mW/cm²) illumination.

FIG. 8 illustrates a schematic view of an energy band acquired by measuring ITO/2PACz and ITO/PEDOT:PSS films by using a UPS, and the remaining materials are examined through the existing documents.

In order to examine a current density-voltage characteristic curve (J-V curve), respective devices are defined as follows (Device A=PEDOT:PSS/PM6:Y6, Device B=2PACz/PM6:Y6, Device C=PM6:Y6:2PACz, Device D=2PACz/PM6:Y6:2PACz).

Table 1 shows J-V curve characteristics in outdoor light (1-sun) and indoor light (LED, FL, and HL).

TABLE 1

| | | | J_{SC} | | | |
|---|---|---|---|---|---|---|
| | | | (outdoor: | | | |
| | | | mA/cm² | | | |
| Light | Device | | indoor: | | | Max. |
| sources | structure | V_{OC} (mV) | μA/cm² | FF (%) | PCE (%) | PCE (%) |
| AM 1.5 G | Device A | 833 ± 5 | 25.5 ± 0.3 | 69.0 ± 0.9 | 14.7 ± 0.3 | 14.9 |
| (100 mW/cm²) | Device B | 822 ± 5 | 25.2 ± 0.1 | 73.2 ± 0.2 | 15.2 ± 0.2 | 15.3 |
| | Device C | 760 ± 8 | 27.2 ± 0.2 | 67.8 ± 0.4 | 14.0 ± 0.5 | 1 [symbol] .3 |
| | Denice D | 842 ± 2 | 27.4 ± 0.1 | 71.2 ± 0.8 | 16.4 ± 0.3 | 16.5 |
| LED 1000 [symbol] | Device A | 663 ± 4 | 136.0 ± 0.2 | 64.9 ± 0.2 | 25. [symbol] ± 0.1 | 25.6 |
| (0.23 mW/cm²) | Device B | 706 ± [symbol] | 139.8 ± 0.1 | 72.9 ± 0.1 | 31.3 ± 0.1 | 31.4 |
| | Device C | 672 ± 7 | 145.1 ± 0.3 | 79.2 ± 0.1 | 33.5 ± 0.1 | 33.5 |
| | Device D | 720 ± [symbol] | 146.6 ± 4.8 | 77.0 ± 0.1 | 36.3 ± 0.2 | 36.5 |
| FL 1000 [symbol] | Device A | 667 ± 8 | 154.6 ± 0.5 | 66.1 ± 0.6 | 25.2 ± 0.3 | 25.4 |
| (0.27 mW/cm²) | Device B | 708 ± 3 | 157.2 ± 1.6 | 73.4 ± 0.3 | 30.2 ± 0.3 | 30.4 |
| | Devite C | 665 ± 3 | 158.4 ± 0.2 | 78.5 ± 0.1 | 30.6 ± 0.1 | 30.7 |
| | Device D | 722 ± 2 | 162.6 ± 3.4 | 77.5 ± 0.1 | 33.7 ± 0.7 | 34.3 |
| HL 1000 [symbol] | Device A | 706 ± 2 | 628.2 ± 28.7 | 68.1 ± 0.3 | 4.3 ± 0.3 | 4.5 |
| (7.0 mW/cm²) | Device B | 753 ± 4 | 659 ± 1.0 | 7 [symbol] .9 ± 0.2 | 5.2 ± 0.1 | 5.3 |
| | Device C | 709 ± 1 | 641.3 ± 1.2 | 79.0 ± 0.1 | 5.1 ± 0.1 | 5.2 |
| | Device D | 762 ± 5 | 664.8 ± 4.2 | 78.5 ± 03 | 5.7 ± 0.1 | 5.8 |

[symbol]

indicates data missing or illegible when filed

As in Table 1 and FIG. 9, power conversion efficiency (PCE) values of Devices A and B show a slight change, while Device C shows a relatively low PCE value. This indicates that in respect to Device C, a 2PACz concentration exerts a bad influence on miscibility of PM6:Y6 in the organic semiconductor layer including 2PACz.

Here, in a 2PACz/PM6:Y6:2PACz device (Device D) to which the 2PACz layer is added, a best PCE value is achieved. The improvement of the performance may be caused by an ionization energy level and recombination loss reduction of vertical phase separation PM6:Y6:2PACz in addition to efficient energy band alignment of 2PACz processed ITO, and it is estimated that this probably improves an internal potential of the device.

FIG. 10 illustrates an EQE spectrum of each device in FIG. 9, and Device D shows a highest EQE spectrum, and this coincides with a current density of the J-V characteristic curve.

FIG. 11 illustrates J-V curve characteristics in LED, FL, and HL 1000 lx, respectively.

As in Table 1, Devices B, C, and D to which 2PACz is applied show different aspects under the indoor light source unlike an AM 1.5G environment.

Device B (2PACz/PM6:Y6) and Device C (PM6:Y6:2PACz) are noteworthy, and open circuit voltages (VOC) of Device B in which 2PACz is processed on ITO and Device C included in PM6:Y6 show higher values in the 2PACz device processed on the ITO.

On the contrary, in Device C having a higher filling rate, 2PACz and PM6:Y6 are caused spontaneously by path providing and recombination reduction of charge transport through layer separation due to efficient vertical phase separation. However, Device C shows relatively low VOC due to insufficient energy level alignment.

Meanwhile, in the 2PACz/PM6:Y6:2PACz device (Device D) for improving both sufficient filling rate and open voltage, a most record-breaking performance may be obtained.

In overall, an excellent indoor performance of Device D is caused by a spontaneous vertical phase separation system obtained due to self-organized 2PACz, and this contributes to developing an interface without a defect, which minimizes recombination loss. Moreover, improvement of FFC and VOC of the device is a result in which hole injection and electron blocking capabilities are maximized due to optimized bending of an energy level generated by semi-fermi level division.

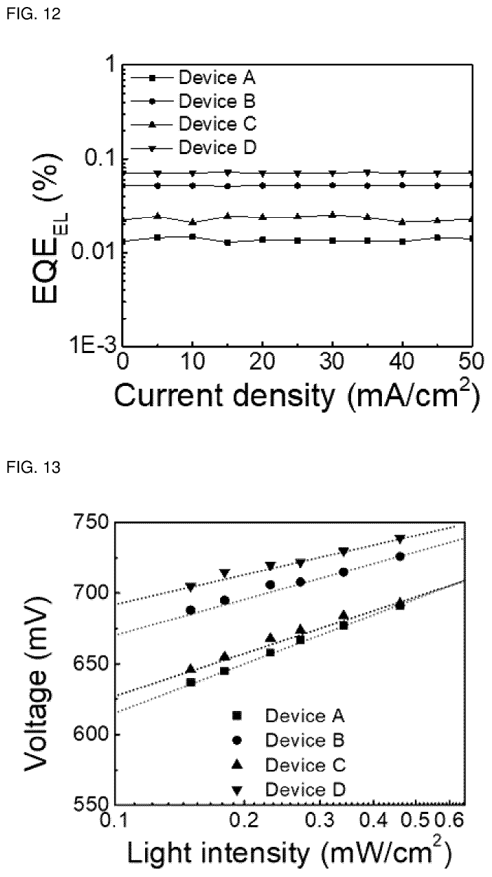

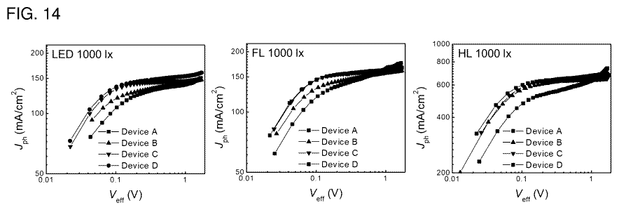

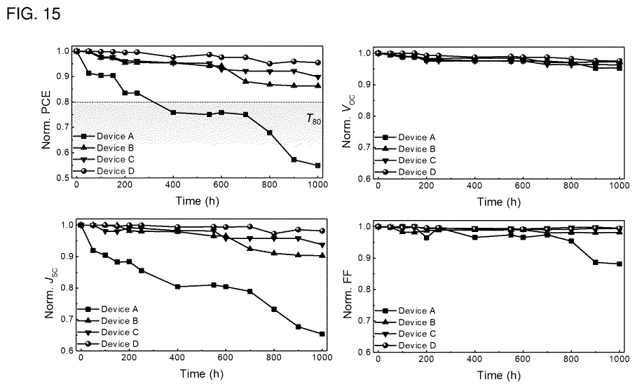

FIG. 12 illustrates EQE_{EL} for identifying energy loss, FIG. 13 illustrates characteristics for each device under an indoor light source for identifying dependency on a J-V incident light intensity, FIG. 14 illustrates a representative Jₚₕ-V_{eff} characteristic curve under LED, FL, and HL 1000 lx illumination, and FIG. 15 illustrates performance parameters (Normalized PCE, V_{OC}, J_{SC}, FF) for surrounding stability of each device.

FIG. 12 illustrates an organic semiconductor layer and an interlayer influence through EQE_{EL} to prove V_{OC} evolution of energy loss.

Energy loss calculated in ΔE₃=−kT ln(EQE_{EL}) is 0.183 eV in Device D, which is lower than the energy loss in Device A by 42 mV (0.225 eV). The energy loss reduced in Device D may block a free charge carrier which may be easily captured by a trap state, and thus reduced non-emission energy loss may be caused.

Therefore, appropriate energy level alignment and suppressed charge recombination loss of Device D is very important to reduce V_{OC}-loss.

FIG. 13 illustrates the evolution of V_{OC} under various light intensities in order to more deeply understand charge recombination dynamics.

Slopes corresponding to Devices D (1.10) and C (1.22) are closer to unity than slopes of Devices B (1.51) and A (1.74), and thus, in Device D, trap assistance recombination and charge transport loss are substantially reduced due to a small area of an interface layer, and as a result, limit potential loss is shown.

In FIG. 14, in order to examine recombination related filling rate (FF) improvement, in charge transport and collection, a photoinduced current density Jₚₕ is evaluated as a function of an effective voltage V_{eff}.

Under LED 1000 lx, Devices C and D show relatively rapid Jₚₕ saturation in V_{eff}=0.162 and 0.166 V, respectively, while Devices B and A show slow Jₚh saturation in V_{eff}=0.206 and 0.232 V, respectively. The rapid Jₚₕ saturation indicates that relatively large amount of current contributes to transportation and collection of diode current and excellent charges.

Further, in Devices C and D, a high filling rate value is shown by reducing a trap density.

A similar recombination trend is observed under FL and HL 1000 lx. Device D approaches saturation current more rapidly than Device A by approximately 50% under the indoor light source.

Finally, in FIG. 15, surrounding stabilities of four devices are compared for 1000 hours under the LED illumination without any capsulation.

Device D maintains PCE of a performance >95%, V_{OC} loss 2.5%, J_{SC} loss 1.9%, and FF loss 0.6%, which is more excellent than other devices.

Excellent surrounding stability may be caused by a Π-Π interaction between adjacent carbazole fragments of 2PACz.

Further, the stability of Device C (PCE >90%) is slightly higher than that of Device B (PCE <86%), and this indicates that chemical adsorption of the PM6:Y6 layer is minimized when the presence of oxygen and moisture molecules are exposed to the atmosphere due to the presence of phase-separated 2PACz.

This effect is more prominent in Device D, and this indicates that a chemical reaction between neighboring atoms is sufficiently suppressed.

In contrast, the rapid decrease in performance (PCE <55%) of Device A is caused due to oxygen and moisture in the air in the case of and PEDOT:PSS-based device, and the diffusion of PEDOT ions between different layers contributes to substantially reducing the performance of the device during stability measurement (>35% J_{SC} loss).

The embodiment of the present invention is disclosed for the purpose of exemplification, and it will be apparent to those skilled in the art that various modifications, changes, and additions for the present invention are possible within the spirit and scope of the present invention, and these modifications, changes, and additions should be considered as falling within the scope of the following claims.

What is claimed is:

1. An indoor photovoltaic cell, comprising:
a transparent lower electrode passing through indoor light;
a self-assembled single-layer based ultra thin 2PACz layer formed on the lower electrode with a predetermined thickness;
an organic semiconductor layer formed on the 2PACz layer by mixing materials for forming a donor layer and an acceptor layer, and 2PACz, generating an exciton by the indoor light, and separating the exciton into a positive charge and a negative charge; and
an upper electrode absorbing the negative charge.

2. The indoor photovoltaic cell of claim 1, wherein the 2PACz layer is formed with a thickness of 3 nm or less.

3. The indoor photovoltaic cell of claim 1, wherein the material for forming the donor layer comprises at least one of PM6 and PM7, and
the material for forming the acceptor layer comprises at least one of Y6 and PC71BM.

4. The indoor photovoltaic cell of claim 1, wherein vertical phase separation is made between the lower electrode and the organic semiconductor layer in the organic semiconductor layer by the 2PACz layer.

5. The indoor photovoltaic cell of claim 4, wherein trap assistance recombination and charge transport loss are reduced by the vertical phase separation.

6. A method for manufacturing an indoor photovoltaic cell, the method comprising:
forming a transparent lower electrode through which indoor light passes on a substrate;
forming a self-assembled single-layer based ultra thin 2PACz layer with a predetermined thickness at an upper portion of the lower electrode;
forming, on the 2PACz layer, an organic semiconductor layer generating an exciton by the indoor light and separating the exciton into a positive charge and a negative charge by mixing materials for forming a donor layer and an acceptor layer, and 2PACz; and
forming an upper electrode absorbing the negative charge on the organic semiconductor layer.

7. The method for manufacturing an indoor photovoltaic cell of claim 6, wherein the 2PACz layer is formed with a thickness of 3 nm or less.
